(19) United States
(12) Patent Application Publication
(10) Pub. No.: US 2022/0123100 A1
(43) Pub. Date: Apr. 21, 2022

(54) SEMICONDUCTOR DEVICE AND METHOD OF MANUFACTURING THE SAME

(71) Applicant: RENESAS ELECTRONICS CORPORATION, Tokyo (JP)

(72) Inventor: Akira MITSUIKI, Tokyo (JP)

(21) Appl. No.: 17/500,313

(22) Filed: Oct. 13, 2021

(30) Foreign Application Priority Data
Oct. 16, 2020 (JP) 2020-174303

(51) Int. Cl. H01L 49/02; H01L 27/01; H01L 21/306

(52) U.S. Cl. CPC H01L 28/24; H01L 21/30608; H01L 27/016

(57) ABSTRACT

Reliability of a semiconductor device is improved, An interlayer insulating film and a pair of conductive layers that separate from each other through the interlayer insulating film are formed on a semiconductor substrate SUB. In this case, a position of each upper surface of the pair of conductive layers is different from a position of an upper surface of the interlayer insulating film, and an insulating film is formed between each upper surface of the pair of conductive layers and the upper surface of the interlayer insulating film. The insulating film has an incline surface that inclines with respect to each upper surface of the pair of conductive layers and die interlayer insulating film. A resistive element is connected to each of the pair of conductive layers, and is formed along the incline surface so as to cover the insulating film.

### CROSS-REFERENCE TO RELATED APPLICATION

The disclosure of Japanese Patent Application No. 2020-174303 filed on Oct. 16, 2020, including the specification, drawings and abstract is incorporated herein by reference in its entirety.

### BACKGROUND

The present invention relates to a semiconductor device and a method of manufacturing the same, and relates to, for example, a semiconductor device including a resistive element formed on an interlayer insulating film and a method of manufacturing the same.

In recent years, resistive elements each having a larger sheet resistance and a small temperature property have been needed in order to improve analog performances of devices. For such a resistive element, a resistive material such as SiCr is used.

There are disclosed techniques listed below.

[Patent Document 1] Japanese Unexamined Patent Application Publication No. 2014-165458

[Patent Document 2] Japanese Unexamined Patent Application Publication No. 2015-115408

For example, the Patent Document 1 discloses an interlayer insulating film formed on a semiconductor substrate, a pair of plug layers formed in the interlayer insulating film, and a resistive element formed on the interlayer insulating film so as to be connected to these layers.

The Patent Document 2 discloses an interlayer insulating film formed on a semiconductor substrate, a pair of wirings formed on the interlayer insulating film, and a resistive element formed on the interlayer insulating film so as to be connected to these wirings.

### SUMMARY

When the resistive material such as SiCr is deposited by, for example, a sputtering method, the resistive material needs to he a thin film in order to obtain a high resistance. However, by the studies made by the present inventors, it has been found that there is a problem of discontinuousness of the deposited resistive material depending on a state of a base material of the resistive material.

Each of FIGS. 1 to 4 is a cross-sectional view showing a method of manufacturing a semiconductor device of a study example studied for this problem by the present inventors.

As shown in FIG. 1, an interlayer insulating film 1 is formed on a semiconductor substrate SUB, and a conductive layer 2 such as a wiring is formed inside the interlayer insulating film 1. An interlayer insulating film 3 is formed on the interlayer insulating film 1, and a hole CH1 is formed inside the interlayer insulating film 3, Inside the hole CH1, a conductive layer 4 is buried as a plug for use in connection with the conductive layer 2.

In order to bury the conductive layer 4 into the hole CH1, a polishing process using, for example, a CMP method is performed. By this polishing process, an upper surface of the conductive layer 4 is recessed from a position of an upper surface of the interlayer insulating film 3 in some cases. For example, at a boundary between the conductive layer 4 and the interlayer insulating film 3, a step is generated between the upper surface of the conductive layer 4 and the upper surface of the interlayer insulating film 3 in some cases.

Next, as shown in FIG. 2, a resistive material film 7a made for example, SiCr is formed on each upper surface of the conductive layer 4 and the interlayer insulating film 3 by a sputtering method. Next, as shown in FIG. 3, a resist pattern RP1 is formed on the resistive material film 7a. Next, as shown in FIG. 4, the resistive material film 7a is patterned while the resist pattern RP1 is used as a mask to form a resistive element 7b that is connected to each of the pair of conductive layers 4.

The resistive material film 7a is formed as a thin film so that the resistive element 7b has a high resistance, and has a thickness of, for example, 3 to 10 nm. The resistive material film 7a is formed by a sputtering method. If a height difference on the step is large, the thickness of the resistive material film 7a at a vertical portion of the step tends to be thin. Therefore, a problem of variation in a resistance value of the resistive element 7b arises. At the worst, a problem of short-circuit on the resistive element 7b arises. Therefore, there is a concern about reduction in reliability of the semiconductor device.

A main purpose of the present application is to improve the reliability of the semiconductor device by the keeping of the thickness of the resistive material film 7a in the portion where the step is generated to control the variation in the resistance value of the resistive element 7b and the short-circuit on the resistive element 7b. Other objects and novel characteristics will be apparent from the description of the present specification and the accompanying drawings.

According to one embodiment, a semiconductor device includes a semiconductor substrate; an interlayer insulating film formed on the semiconductor substrate; a pair of conductive layers formed on the semiconductor substrate; and a resistive element connected to each of the pair of conductive layers. In this case, a position of each upper surface of the pair of conductive layers is different from a position of an upper surface of the interlayer insulating film, a first insulating film having an incline surface that inclines with respect to each upper surface of the pair of conductive layers and the interlayer insulating film is formed between each upper surface of the pair of conductive layers and the upper surface of the interlayer insulating film, and the resistive element is formed along the incline surface so as to cover the first insulating film.

According to one embodiment, a method of manufacturing a semiconductor device includes: a step (a) of forming an interlayer insulating film and a pair of conductive layers on a semiconductor substrate; a step (b) of forming a first insulating film on each upper surface of the pair of conductive layers and the interlayer insulating film; a step (c) of exposing at least a part of each upper surface of the pair of conductive layers by an anisotropic etching process to the first insulating film; a step (d) of forming a resistive material film on each upper surface of the pair of conductive layers and the interlayer insulating film; and a step (e) of forming a resistive element connected to each of the pair of conductive layers by selectively patterning the resistive material film. In this case, in the step (a), a position of each upper surface of the pair of conductive layers is different from a position of an upper surface of the interlayer insulating film. In the step (c), the first insulating film remains between each upper surface of the pair of conductive layers and the upper surface of the interlayer insulating film, an incline surface that inclines with respect to each upper surface of the pair of conductive layers and the interlayer insulating film is formed in the first insulating film, In the step (e) the resistive element is formed along the incline surface so as to cover the first insulating film.

According to one embodiment, the reliability of the semiconductor device can be improved.

### BRIEF DESCRIPTIONS OF THE DRAWINGS

FIG. 1 is a cross-sectional view showing a step of manufacturing a semiconductor device according to a study example.

FIG. 2 is a cross-sectional view showing a step of manufacturing the semiconductor device, continued from FIG. 1.

FIG. 3 is a cross-sectional view showing a step of manufacturing the semiconductor device, continued from FIG. 2.

FIG. 4 is a cross-sectional view showing a step of manufacturing the semiconductor device, continued from FIG. 3.

FIG. 5 is a cross-sectional view showing a semiconductor device according to a first embodiment.

FIG. 6 is a plan view showing the semiconductor device according to the first embodiment.

FIG. 7 is a cross-sectional view showing a step of manufacturing the semiconductor device according to the first embodiment.

FIG. 8 is a cross-sectional view showing a step of manufacturing the semiconductor device, continued from FIG. 7.

FIG. 9 is a cross-sectional view showing a step of manufacturing the semiconductor device, continued from FIG. 8.

FIG. 10 is a cross-sectional view showing a step of manufacturing the semiconductor device, continued from FIG. 9.

FIG. 11 is a cross-sectional view showing a step of manufacturing the semiconductor device, continued from FIG. 10.

FIG. 12 is a cross-sectional view showing a step of manufacturing the semiconductor device, continued from FIG. 11.

FIG. 13 is a cross-sectional view showing a step of manufacturing the semiconductor device, continued from FIG. 12.

FIG. 14 is a cross-sectional view showing a step of manufacturing the semiconductor device, continued from FIG. 13.

FIG. 15 is a cross-sectional view showing a semiconductor device according to a second embodiment.

FIG. 16 is a cross-section& view showing a step of manufacturing the semiconductor device according to the second embodiment.

FIG. 17 is a cross-sectional view showing a step of manufacturing the semiconductor device, continued from FIG. 16.

FIG. 18 is a cross-sectional view showing a step of manufacturing the semiconductor device, continued from FIG. 17.

FIG. 19 is a cross-sectional view showing a step of manufacturing the semiconductor device, continued from FIG. 18.

FIG. 20 is a cross-sectional view showing a step of manufacturing the semiconductor device, continued from FIG. 19.

FIG. 21 is a cross-sectional view showing a step of manufacturing the semiconductor device, continued from FIG. 20.

FIG. 22 is a cross-sectional view showing a step of manufacturing the semiconductor device, continued from FIG. 21.

FIG. 23 is a cross-sectional view showing a step of manufacturing the semiconductor device, continued from FIG. 22.

FIG. 24 is a cross-sectional view showing a semiconductor device according to a third embodiment.

FIG. 25 is a cross-sectional view showing a step of manufacturing the semiconductor device according to the third embodiment.

FIG. 26 is a cross-sectional view showing a step of manufacturing the semiconductor device, continued from FIG. 25.

FIG. 27 is a cross-sectional view showing a step of manufacturing the semiconductor device, continued from FIG. 26.

FIG. 28 is a cross-sectional view showing a step of manufacturing the semiconductor device, continued from FIG. 27.

FIG. 29 is a cross-sectional view showing a step of manufacturing the semiconductor device, continued from FIG. 28.

FIG. 30 is a cross-sectional view showing a step of manufacturing the semiconductor device, continued from FIG. 29.

FIG. 31 is a cross-section& view showing a step of manufacturing the semiconductor device, continued from FIG. 30.

FIG. 32 is a cross-sectional view showing a semiconductor device according to a fourth embodiment.

FIG. 33 is a cross-sectional view showing a step of manufacturing the semiconductor device according to the fourth embodiment.

FIG. 34 is a cross-sectional view showing a step of manufacturing the semiconductor device, continued from FIG. 33.

FIG. 35 is a cross-section& view showing a step of manufacturing the semiconductor device, continued from FIG. 34.

FIG. 36 is a cross-sectional view showing a step of manufacturing the semiconductor device, continued from FIG. 35.

### DETAILED DESCRIPTION

Embodiments will be described in detail below on the basis of the accompanying drawings. In all the drawings for use in describing the embodiments, the members having the same function are denoted with the same reference symbols, and the repetitive description thereof will be omitted. In addition, the description of the same or similar portions is not repeated in principle unless particularly required in the following embodiments.

Further, in some drawings used in the present application, hatching is omitted even in the cross-sectional views so as to make the drawings easy to see in some cases. And, hatching is added even in the plan views in some cases.

An “X” direction, a “Y” direction and a “Z” direction described in the present application cross one another, and are orthogonal to one another. The present application describes the Z direction as a vertical direction, a height direction or a thickness direction of a certain structure. The term “planar view” in the present application means that a plane made by the X direction and the Y direction is viewed in the Z direction.

### First Embodiment

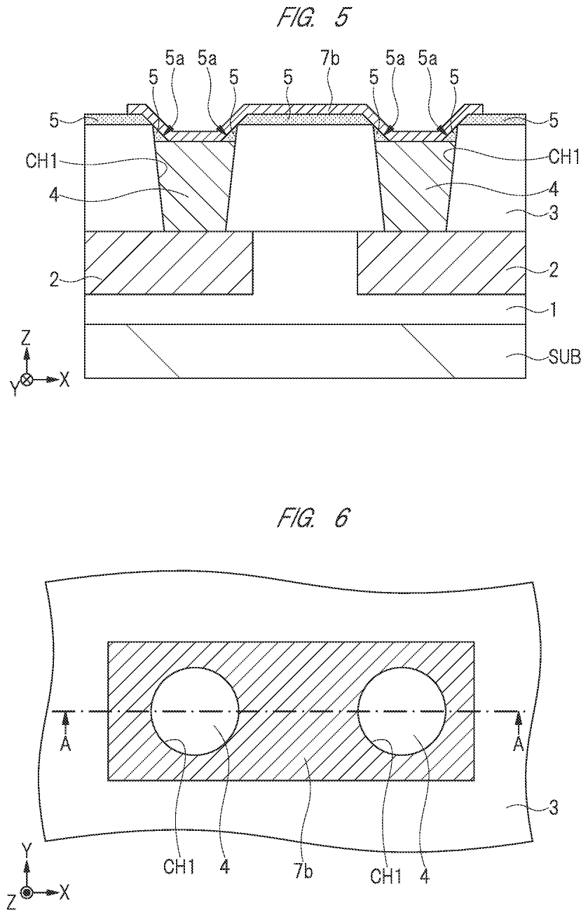

With reference to FIGS. 5 to 14, a semiconductor device according to a first embodiment and a method of manufacturing the same will be explained below.

### Structure of Semiconductor Device According to First Embodiment

First, with reference to FIGS. 5 and 6, a structure of the semiconductor device will be explained. FIG. 6 is a plan view showing the semiconductor device. FIG. 5 is a cross-sectional view taken along a line A-A of FIG. 6.

As shown in FIG. 5, the semiconductor device according to the first embodiment includes a semiconductor substrate SUB, an interlayer insulating film 1, a plurality of conductive layers 2, an interlayer insulating film 3, a plurality of conductive layers 4, an insulating film 5 and a resistive element 7b.

The semiconductor substrate SUB is preferably made of single crystal silicon (Si) having a specific resistance of about 1 to 10 Ωcm, and is made of, for example, p-type single crystal silicon. Although not illustrated, a semiconductor element such as a field effect transistor is formed in the semiconductor substrate SUB.

On the semiconductor substrate SUB, the interlayer insulating film 1 made of, for example, silicon oxide (SiO₂) is formed. In the interlayer insulating film 1, the plurality of conductive layers 2 are formed. The conductive layer 2 is, for example, a wiring formed by a damascene technique. In the drawings, the interlayer insulating film 1 and the conductive layer 2 in one layer are illustrated. However, a multilayered wiring layer may be formed by formation of such interlayer insulating film 1 and conductive layer 2 in a plurality of layers.

On the interlayer insulating film 1, the interlayer insulating film 3 made of, for example, silicon oxide (SiO₂) and the plurality of conductive layers 4 are formed. The drawings illustrate a pair of conductive layers 4 among the plurality of conductive layers 4, the pair of conductive layers 4 being connected to the conductive layers 2 in a lower layer and separating from each other through the interlayer insulating film 3.

The conductive layer 4 according to the first embodiment is buried inside the hole CH1 that is formed inside the interlayer insulating film 3. The conductive layer 4 includes the following barrier metal film and conductive film. The barrier metal film is formed on a side surface and a bottom surface of the hole CH1, and is a film made of, for example, titanium (Ti), tantalum (Ta) or titanium nitride (TiN), tantalum nitride (TaN) or a layered film that is formed by appropriately layering these materials. The conductive film is buried inside the hole CH1 through the barrier metal film, and is made of, for example, tungsten (W).

The step is generated between each upper surface of the pair of conductive layers 4 and the upper surface of the interlayer insulating film 3. In other words, a position of each upper surface of the pair of conductive layers 4 is different from a position of the upper surface of the interlayer insulating film 3, and is lower than the position of the upper surface of the interlayer insulating film 3.

The insulating film 5 is formed between each upper surface of the pair of conductive layers 4 and the upper surface of the interlayer insulating film 3. The insulating film 5 is made of, for example, silicon oxynitride (SiON) or silicon nitride (SiN).

In the first embodiment, the insulating film 5 has a portion that is formed so as to cover a part of each upper surface of the pair of conductive layers 4 and a portion that is formed so as to cover the upper surface of the interlayer insulating film 3. These portions of the insulating film 5 may separate from or unite with each other. It is important to form the insulating film 5 at least in the portion where the step is generated.

A resistive element 7b is formed on each upper surface of the pair of conductive layers 4 and above the upper surface of the interlayer insulating film 3 through the insulating film 5. The resistive element 7b is made of the resistive material film 7a as described later, and the resistive material film 7a is preferably made of a metal material having a higher sheet resistance than that of a material configuring the conductive layer 2 or the conductive layer 4, and is made of, for example, chromium silicon (SiCr).

The resistive element 7b is connected to each of the pair of conductive layers 4. In this manner, the resistive element 7b can be electrically connected to a semiconductor element formed in other region of the semiconductor substrate SUB or others through the conductive layer 2 or the conductive layer 4 that is formed in a lower layer of the resistive element 7b. As shown in the plan view of FIG. 6, note that the pair of conductive layers 4 are arranged so as to overlap the resistive element 7b and to be included in the resistive element 7b in a planar view.

The insulating film 5 has an incline surface 5a that inclines with respect to each upper surface of the pair of conductive layers 4 and the interlayer insulating film 3. An angle that is made by the incline surface 5a and the upper surface of the conductive layer 4 or an angle that is made by the incline surface 5a and the upper surface of the interlayer insulating film 3 is within a range of 40 to 50 degrees, and is preferably 45 degrees.

In the portion where the step is generated (the portion between each upper surface of the pair of conductive layers 4 and the upper surface of the interlayer insulating film 3), the resistive element 7b is formed along the incline surface 5a so as to cover the insulating film 5. In the first embodiment, the incline surface 5a inclines so as to ascend from each of the pair of conductive layers 4 toward the interlayer insulating film 3.

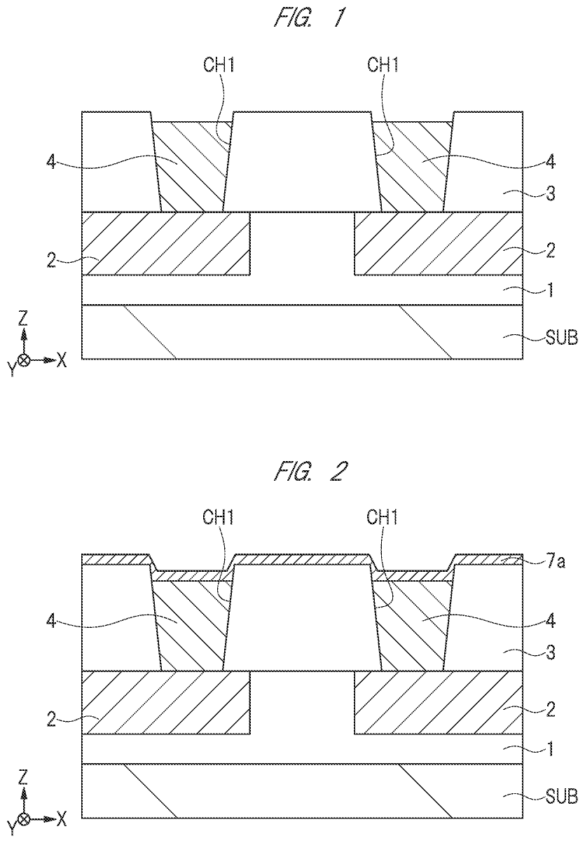

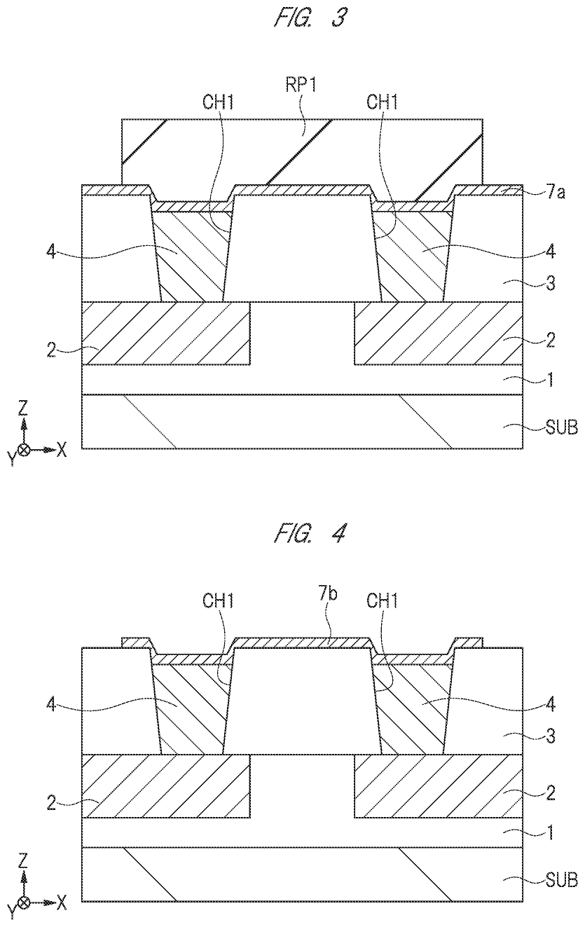

As explained with reference to FIGS. 1 to 4, the study example has the problem of the easiness of the reduction of the thickness of the resistive material film 7a in the portion where the step is generated. Therefore, the problem of the variation in the resistance value of the resistive element 7b and the problem of the short-circuit on the resistive element 7b arise.

In the first embodiment, the insulating film 5 having the incline surface 5a is formed in the portion where the step is generated. Therefore, even if the height difference on the step is large, the thickness of the resistive material film 7a is kept when the resistive material film 7a that is the base material of the resistive element 7b is formed by the sputtering method. Therefore, the problems that are caused in the study example can be solved. Thus, the reliability of the semiconductor device can be improved.

### Method of Manufacturing Semiconductor Device According to First Embodiment

A method of manufacturing the semiconductor device will be explained below with reference to FIGS. 7 to 14. Note that a material of each structural body or others is as described above, and therefore, the explanation for this will be omitted below.

First, As shown in FIG. 7, the semiconductor substrate SUB is prepared. Next, although not illustrated, a semiconductor element such as a field effect transistor is formed in the semiconductor substrate SUB.

Next, on the semiconductor substrate SUB, the interlayer insulating film 1 is formed by, for example, a CVD (Chemical Vapor Deposition) method so as to cover the semiconductor element. Next, in the interlayer insulating film 1, a plurality of conductive layers 2 are formed. A trench is formed inside the interlayer insulating film 1, a conductive film mainly containing copper is buried inside the trench, and the excessive conductive film outside the trench is removed by a CMP (Chemical Mechanical Polishing) method, so that the conductive layer 2 is formed.

Next, on the interlayer insulating film 1, the interlayer insulating film 3 is formed so as to cover the plurality of conductive layers 2 by, for example, a CVD method. Next, a plurality of holes CH1 that reach the plurality of conductive layers 2 and that separate from one another are formed inside the interlayer insulating film 3 by a photolithography method and an etching process. Next, the conductive layer 4 is buried inside each of the plurality of holes CH1.

The conductive layer 4 is formed as follows. First, a barrier metal film is formed on the upper surface of the interlayer insulating film 3 and inside the hole CH1 by, for example, a CVD method or a sputtering method. Next, on the barrier metal film, a conductive film is formed by, for example, a CVD method so as to fill the hole CH1. Next, the conductive film and the barrier metal film that are formed outside the hole CH1 are removed by a polishing process using a CMP method. In this manner, the conductive layer 4 including the conductive film and the barrier metal film is buried inside the hole CH1.

In this case, if the conductive film and the barrier metal film remain on the upper surface of the interlayer insulating film 3 outside the hole CH1, there is a concern about formation of a leakage path between the conductive layers 4. Therefore, in the first embodiment, the polishing process is performed so as to cause slight over-etching under a condition of a higher etching rate for the conductive layer 4 than that for the interlayer insulating film 3.

Because of the polishing process, the position of the upper surface of the conductive layer 4 is different from the position of the upper surface of the interlayer insulating film 3, and is lower than the position of the upper surface of the interlayer insulating film 3. In other words, the step is generated between the upper surface of the conductive layer 4 and the upper surface of the interlayer insulating film 3.

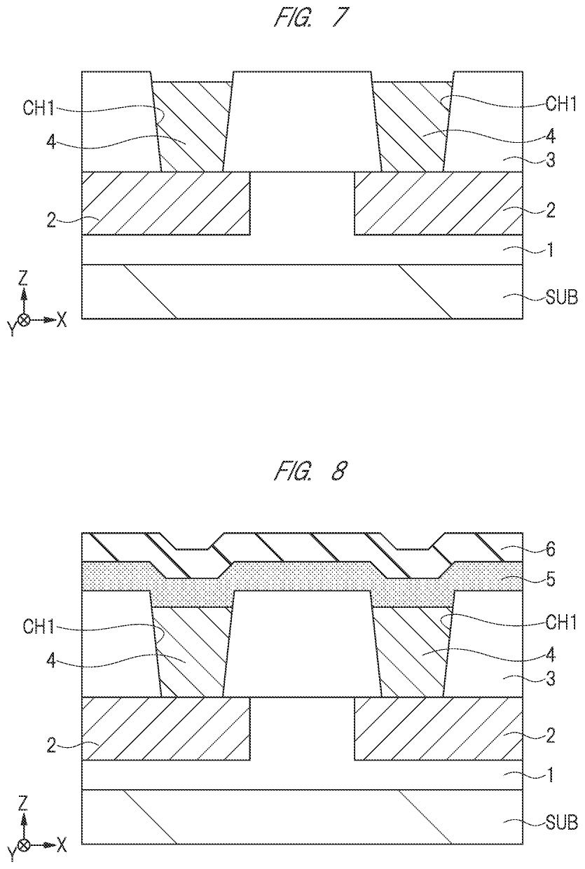

Next, as shown in FIG. 8, on each upper surface of the pair of conductive layers 4 and the interlayer insulating film 3, the insulating film 5 is formed by, for example, a CVD method so as to cover the step. A thickness of the insulating film 5 at this stage is, for example, 10 to 50 nm.

Next, on the insulating film 5, the insulating film 6 is formed by, for example, a CVD method. The insulating film 6 is made of a material that is different from the material configuring the insulating film 5, and is made of for example, silicon oxide (SiO₂). A thickness of the insulating film 6 at this stage is, for example, 30 to 100 nm.

In the first embodiment, note that silicon oxynitride (SiON) or silicon nitride (SiN) is exemplified for the insulating film 5, and silicon oxide (SiO₂) is exemplified for the insulating film 6. However, each material of the insulating film 5 and the insulating film 6 is not limited to this, and may be a different material from each other.

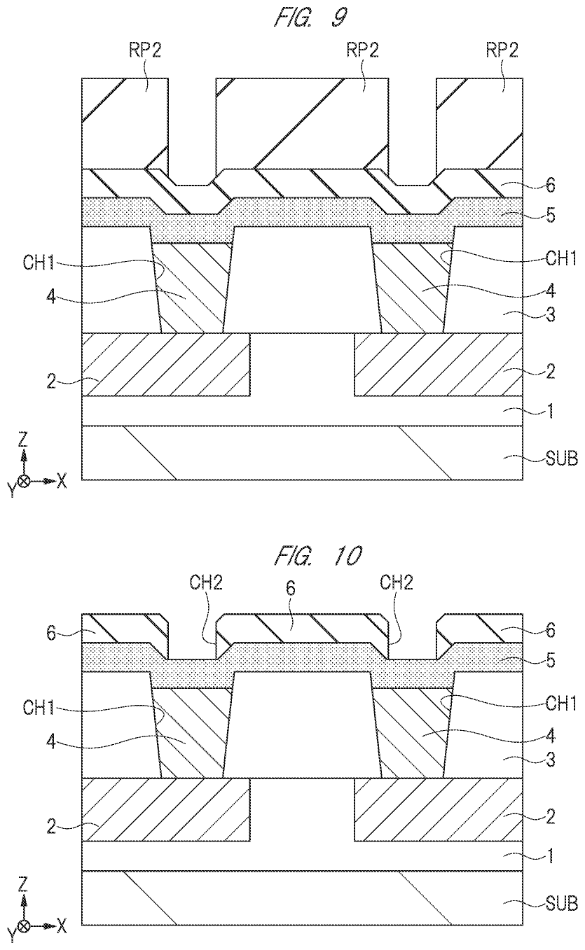

Next, as shown in FIG. 9, a resist pattern RP2 having a pattern opening a part of each upper surface of the pair of conductive layers 4 is formed on the insulating film 6.

Next, as shown in FIG. 10, a pair of holes CH2 are formed inside the insulating film 6 by an anisotropic etching process using the resist pattern RP2 as a mask. Then, the resist pattern RP2 is removed by an aching process.

This anisotropic etching process is performed under a condition making it difficult to etch the insulating film 5 but easy to etch the insulating film 6. In other words, during the etching process for the insulating film 6, the insulating film 5 functions as an etching stopper.

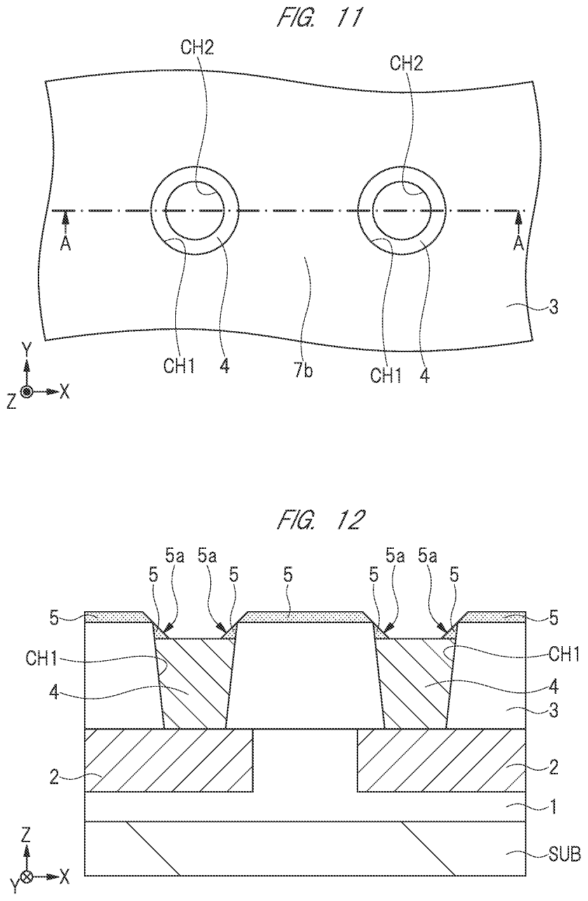

FIG. 11 shows a plan view of the semiconductor device in the manufacturing step of FIG. 10. As shown in FIG. 11, each of the pair of holes CH2 that are formed as shown in FIG. 10 is formed so as to overlap the hole CH1 (the conductive layer 4) in a planar view and is included in the hole CH1 (the conductive layer 4) in a planar view. In other words, each of the pair of holes CH2 is formed directly on the hole CH1 (the conductive layer 4) in a cross-sectional view.

A diameter of the hole CH2 is smaller than a diameter of the hole CH1. If the diameter of the hole CH2 is larger than the diameter of the hole CH1, it is difficult to leave the insulating film 5 in the portion where the step is generated, by a later manufacturing step.

Next, as shown in FIG. 12, an anisotropic etching process is performed to the insulating film 5 and the insulating film 6. This anisotropic etching process is performed under a condition having almost the same etching rate between the insulating film 5 and the insulating film 6. This anisotropic etching process is performed by an EPD (End Point Detector) technique so that an etching apparatus can detect change in a chemical component from the insulating film 6 to the insulating film 5. In other words, this anisotropic etching process is performed until the insulating film 5 is exposed by removal of the insulating film 6 formed on the insulating film 5.

By this anisotropic etching process, the insulating film 5 remains between each upper surface of the pair of conductive layers 4 and the upper surface of the interlayer insulating 3. In the first embodiment, the insulating film 5 remains so as to cover at least a part of each upper surface of the pair of conductive layers 4 and also remains so as to cover the upper surface of the interlayer insulating film 3. In a portion not covered with the insulating film 5, a part of the upper surface of the conductive layer 4 is exposed.

The insulating film 5 remaining between each upper surface of the pair of conductive layers 4 and the upper surface of the interlayer insulating film 3 is provided with the incline surface 5a that inclines with respect to each upper surface of the pair of conductive layers 4 and the interlayer insulating film 3 by the anisotropic etching process.

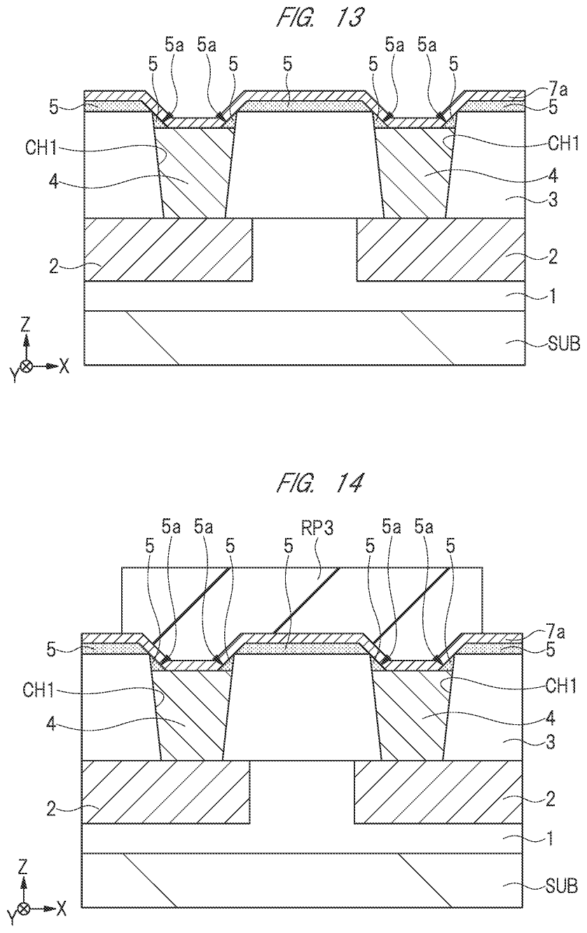

Next, as shown in FIG. 13, the resistive material film 7a is formed on each upper surface of the pair of conductive layers 4 and an upper surface of the insulating film 5 that is formed on the upper surface of the interlayer insulating film 3 by a sputtering method. A thickness of the resistive material film 7a at this stage is, for example, 3 to 10 nm.

Next, as shown in FIG. 14, a resist pattern RP3 having a pattern covering at least each upper surface of the pair of conductive layers 4 and a portion between the pair of conductive layers 4 is formed on the resistive material film 7a.

Next, the resistive material film 7a is selectively patterned by an anisotropic etching process using the resist pattern RP3 as a mask. In this manner, as shown in FIGS. 5 and 6, the resistive element 7b connected to the pair of conductive layers 4 is formed. The resistive element 7b is formed along the incline surface 5a so as to cover the insulating film 5. Then, the resist pattern RP3 is removed by an aching process.

Then, although not illustrated, an interlayer insulating film and a conductive layer such as a plug and a wiring are formed as an upper-layer wiring structure on the resistive element 7b, and the semiconductor device according to the first embodiment is manufactured.

### Second Embodiment

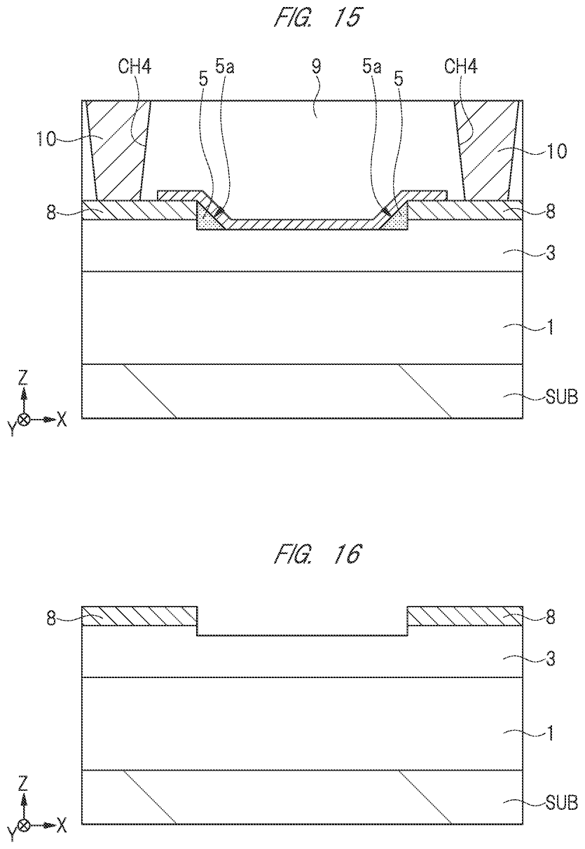

With reference to FIGS. 15 to 23, a semiconductor device according to a second embodiment and a method of manufacturing the same will be explained below. In the following explanation, differences from the first embodiment will be mainly explained, and the explanation for overlapping points with the first embodiment will be omitted.

### Structure of Semiconductor Device According to Second Embodiment

In the first embodiment, the pair of conductive layers 4 are formed inside the interlayer insulating film 3. In the second embodiment, as shown in FIG. 15, a pair of conductive layers 8 that separate from each other through the interlayer insulating film 3 are formed on the upper surface of the interlayer insulating film 3. The pair of conductive layers 8 are a local wiring for use in connecting the resistive element 7b to a wiring in an upper layer, and is made of, for example, titanium nitride (TiN).

On the upper surface of the interlayer insulating film 3, an interlayer insulating film 9 that is made of, for example, silicon oxide (SiO₂) is formed so as to cover the resistive element 7b and the pair of conductive layers 8. A hole CH 4 reaching the pair of conductive layers 8 is formed inside the interlayer insulating film 9, and a conductive layer 10 serving as a plug for connection to the conductive layer 8 is buried inside the hole CH4. A material configuring the conductive layer 10 is the same as that of the conductive layer 3 of the first embodiment.

Even in the second embodiment, the step is generated between each upper surface of the pair of conductive layers 8 and the upper surface of the interlayer insulating film 3. In other words, a position of each upper surface of the pair of conductive layers 8 is different from a position of the upper surface of the interlayer insulating film 3, and is higher than the position of the upper surface of the interlayer insulating film 3.

In the portion where the step is generated, the insulating film 5 is formed. The insulating film 5 is formed so as to cover a part of the upper surface of the interlayer insulating film 3, and has the incline surface 5a that inclines with respect to each upper surface of the pair of conductive layers 8 and the interlayer insulating film 3.

In the second embodiment, the incline surface 5a inclines so as to descend from each of the pair of conductive layers 8 toward the interlayer insulating film 3. An angle that is made by the incline surface 5a and the upper surface of the conductive layer 8 or an angle that is made by the incline surface 5a and the upper surface of the interlayer insulating film 3 is within a range of 40 to 50 degrees as similar to the first embodiment, and is preferably 45 degrees.

The resistive element 7b is formed on each upper surface of the pair of conductive layers 8 and the interlayer insulating film 3 so as to be connected to each of the pair of conductive layers 8. In the portion where the step is generated, the resistive element 7b is formed along the incline surface 5a so as to cover the insulating film 5. Therefore, even in the second embodiment, the problems that are caused in the study example can be solved, and the reliability of the semiconductor device can be improved.

### Method of Manufacturing Semiconductor Device According to Second Embodiment

First, as shown in FIG. 16, on the semiconductor substrate SUB, the interlayer insulating film 1 and the interlayer insulating film 3 are formed. The steps of manufacturing the interlayer insulating film 1 and the interlayer insulating film 3 are the same as those of the first embodiment.

Next, on the upper surface of the interlayer insulating film 3, a conductive film made of titanium nitride (TiN) or others is formed by, for example, a CVD method. A thickness of the conductive film at this stage is, for example, 20 to 40 nm. Next, the conductive film is selectively patterned by a photolithography technique and an etching process, so that the pair of conductive layers 8 are formed.

At the time of patterning, the over-etching is performed in order to avoid the conductive film from remaining on the upper surface of the interlayer insulating film 3. Therefore, the upper surface of the interlayer insulating film 3 not covered with the conductive layer 8 is slightly recessed.

In the manner, by the manufacturing step of FIG. 16, the step is generated between each upper surface of the pair of conductive layers 8 and the upper surface of the interlayer insulating film 3. In other words, a position of each upper surface of the pair of conductive layers 8 is different from a position of the upper surface of the interlayer insulating film 3, and is higher than the position of the upper surface of the interlayer insulating film 3.

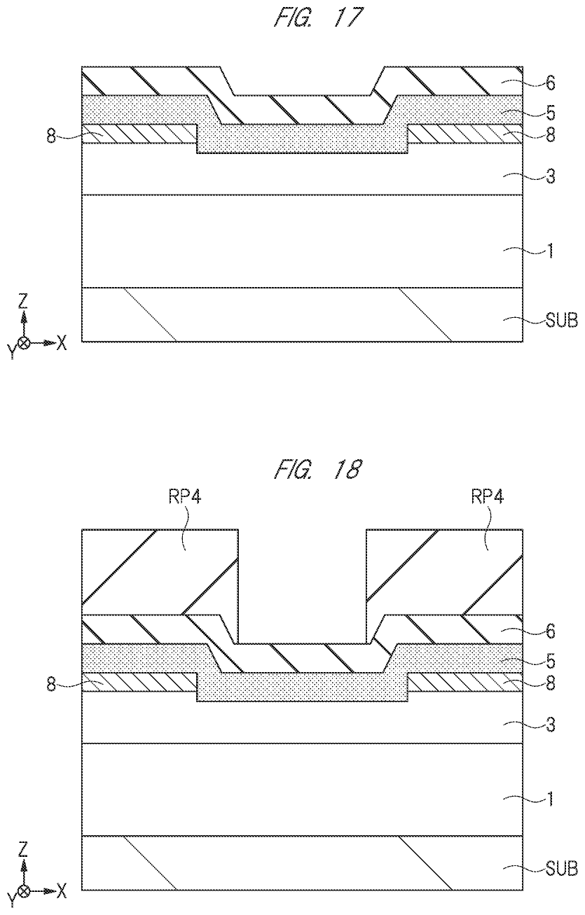

Next, as shown in FIG. 17, the insulating film 5 is formed on each upper surface of the pair of conductive layers 8 and the interlayer insulating film 3 so as to cover the step, and the insulating film 6 is formed on the insulating film 5.

Next, as shown in FIG. 18, a resist pattern RP4 having a pattern opening a portion between the pair of conductive layers 8 is formed on the insulating film 6.

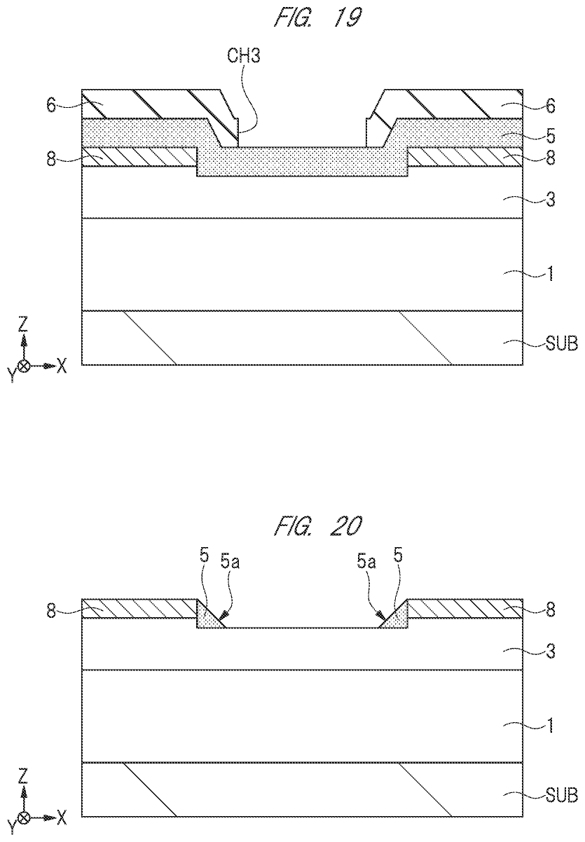

Next, as shown in FIG. 19, a hole CH3 is formed inside the insulating film 6 positioned between the pair of conductive layers 4 by an anisotropic etching process using the resist pattern RP4 as a mask. Then, the resist pattern RP4 is removed by an ashing process.

Next, as shown in FIG. 20, an anisotropic etching process is performed to the insulating film and the insulating film 6. This anisotropic etching process is performed under a condition having almost the same etching rate between the insulating film 5 and the insulating film 6. This anisotropic etching process is performed by an EPD (End Point Detector) technique. In other words, this anisotropic etching process is performed until each upper surface of the pair of conductive layers 8 is exposed by removal of the insulating film 5 and the insulating film 6 that are formed on each upper surface of the pair of conductive layers 8.

By this anisotropic etching process, the insulating film 5 remains between each upper surface of the pair of conductive layers 8 and the upper surface of the interlayer insulating film 3. In the second embodiment, the insulating film 5 remains so as to cover a part of the upper surface of the interlayer insulating film 3.

The remaining insulating film 5 is provided with the incline surface 5a that inclines with respect to each upper surface of the pair of conductive layers 8 and the interlayer insulating film 3 by the anisotropic etching process.

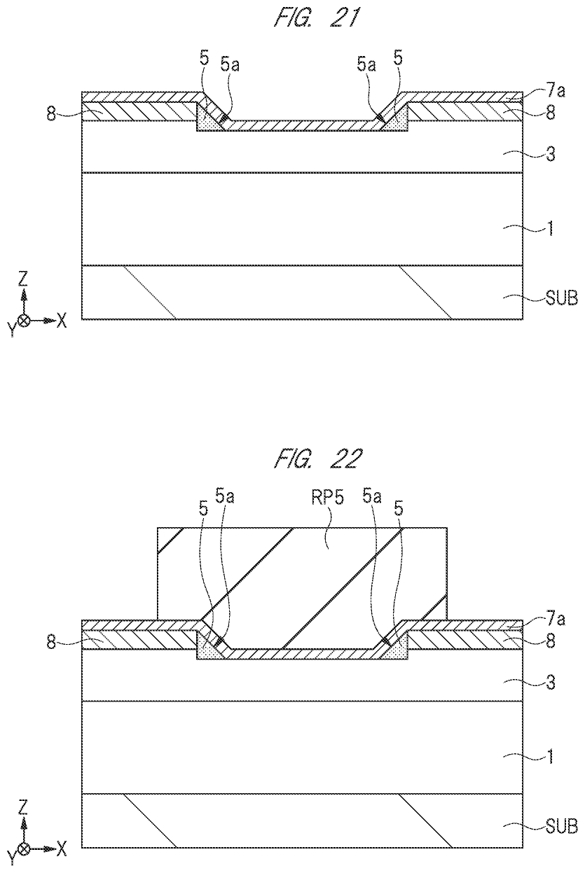

Next, as shown in FIG. 21, the resistive material film 7a is formed on each upper surface of the pair of conductive layers 8 and the interlayer insulating film 3 so as to cover the insulating film 5 by a sputtering method.

Next, as shown in FIG. 22, a resist pattern RP5 having a pattern covering a part of the upper surfaces of the pair of conductive layers 8 and a portion between the pair of conductive layers 8 is formed on the resistive material film 7a.

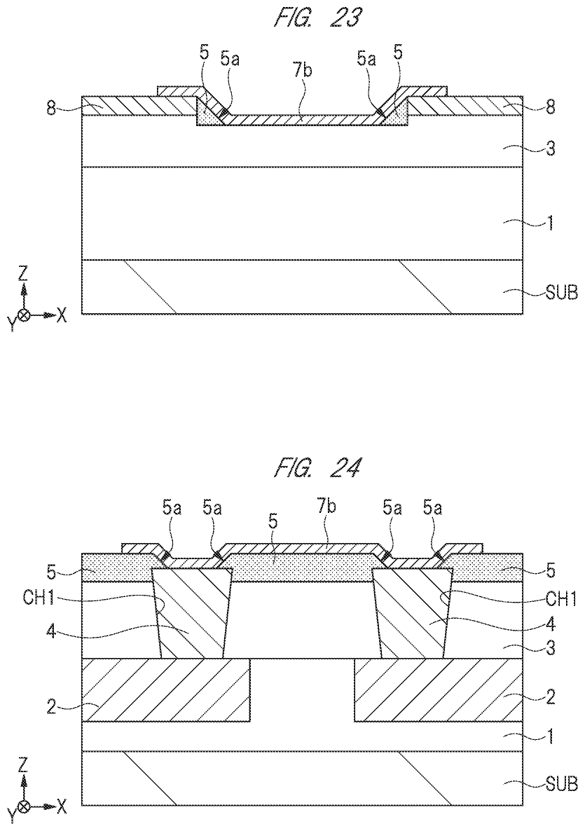

Next, as shown in FIG. 23, the resistive material film 7a is selectively patterned by an anisotropic etching process using the resist pattern RP5 as a mask. In this manner, the resistive element 7b connected to the pair of conductive layers 8 is formed. The resistive element 7b is formed along the incline surface 5a so as to cover the insulating film 5. Then, the resist pattern RP5 is removed by an as hang process.

Then, through the following manufacturing steps, the semiconductor device shown in FIG. 15 is manufactured. On the interlayer insulating film 3, an interlayer insulating film 9 is formed so as to cover the resistive element 7b and the pair of conductive layers 8 by, for example, a CVD method. Next, inside the interlayer insulating film 9, a hole CH4 reaching the pair of conductive layers 8 is formed by a photolithography technique and an etching process. Next, by the manufacturing steps that are the same as those for the conductive layer 3 of the first embodiment, a conductive layer 10 is buried inside the hole CH4.

### Third Embodiment

With reference to FIGS. 24 to 31, a semiconductor device according to a third embodiment and a method of manufacturing the same will be explained below. In the following explanation, differences from the first embodiment will be mainly explained, and the explanation for overlapping points with the first embodiment will be omitted.

### Structure of Semiconductor Device According to Third Embodiment

In the first embodiment, the upper surface of the conductive layer 4 is recessed from the upper surface of the interlayer insulating film 3. In the third embodiment, as shown in FIG. 24, a part of the conductive layer 4 protrudes from the upper surface of the interlayer insulating film 3.

Even in the third embodiment, the step is generated between each upper surface of the pair of conductive layers 4 and the upper surface of the interlayer insulating film 3. In other words, a position of each upper surface of the pair of conductive layers 4 is different from a position of the upper surface of the interlayer insulating film 3, and is higher than the position of the upper surface of the interlayer insulating film 3.

In the portion where the step is generated, the insulating film 5 is formed. The insulating film 5 is formed so as to cover a part of each upper surface of the pair of conductive layers 4 and the upper surface of the interlayer insulating film 3, and has the incline surface 5a that inclines with respect to each upper surface of the pair of conductive layers 4 and the interlayer insulating film 3.

In the third embodiment, the incline surface 5a inclines so as to ascend from each of the pair of conductive layers 4 toward the interlayer insulating film 3. An angle that is made by the incline surface 5a and the upper surface of the conductive layer 4 or an angle that is made by the incline surface 5a and the upper surface of the interlayer insulating film 3 is within a range of 40 to 50 degrees as similar to the first embodiment, and is preferably 45 degrees.

The resistive element 7b is formed on each upper surface of the pair of conductive layers 4 and the upper surface of the insulating film 5 formed on the upper surface of the interlayer insulating film 3 so as to be connected to each of the pair of conductive layers 4. In the portion where the step is generated, the resistive element 7b is formed along the incline surface 5a so as to cover the insulating film 5. Therefore, even in the third embodiment, the problems that are caused in the study example can be solved, and the reliability of the semiconductor device can be improved.

### Method of Manufacturing Semiconductor Device According to Third Embodiment

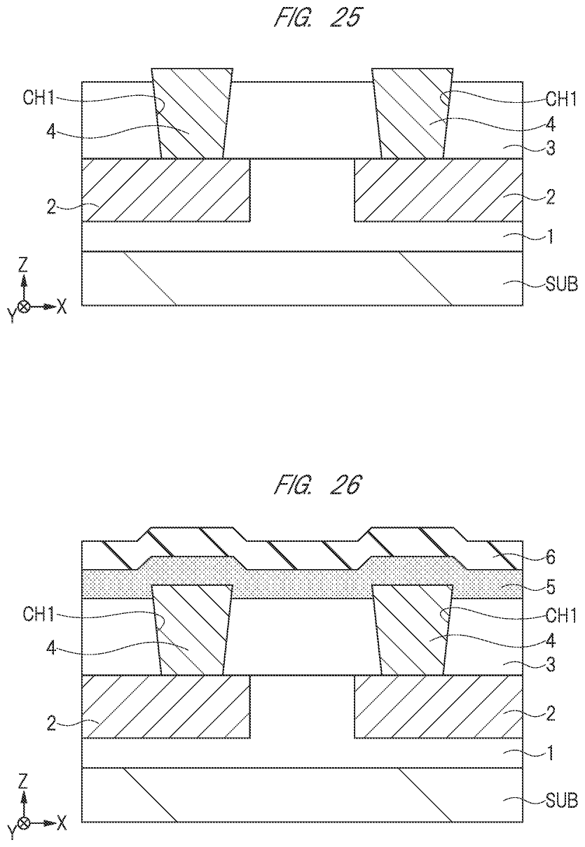

First, as shown in FIG. 25, the interlayer insulating film 1, the conductive layer 2, the interlayer insulating film 3 and the conductive layer 4 are formed on the semiconductor substrate SUB. The steps of manufacturing these components are the same as those of the first embodiment. However, in the third embodiment, under a condition having a higher etching rate for the interlayer insulating film 3 than that for the conductive layer 4, a polishing process is performed by a CMP method so as to perform slight over-etching.

By the polishing process, a position of the upper surface of the conductive layer 4 is different from a position of the upper surface of the interlayer insulating film 3, and is higher than the position of the upper surface of the interlayer insulating film 3. In other words, the step is generated between the upper surface of the conductive layer 4 and the upper surface of the interlayer insulating film 3.

Next, as shown in FIG. 26, the insulating film 5 is formed on each upper surface of the pair of conductive layers 4 and the interlayer insulating film 3 so as to cover the step, and the insulating film 6 is formed on the insulating film 5.

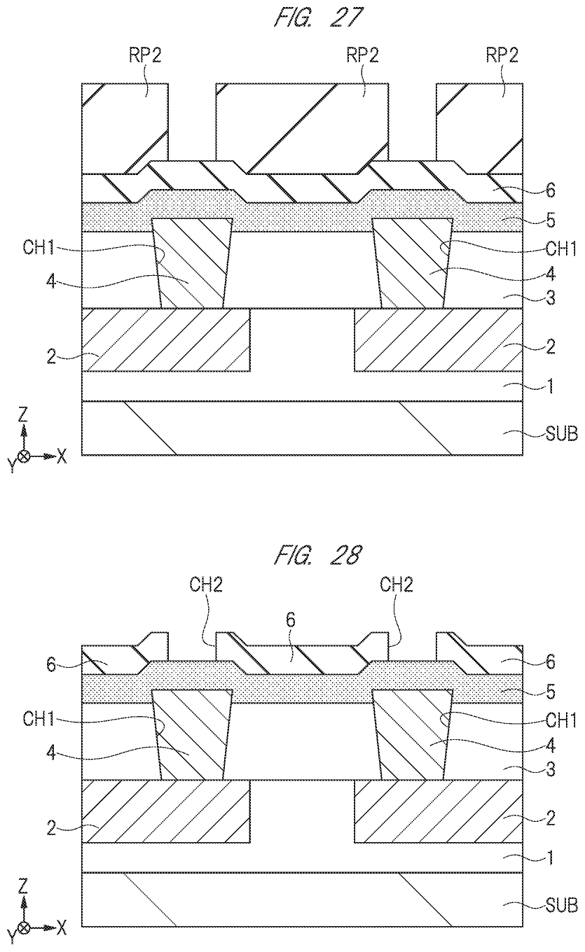

Next, as shown in FIG. 27, a resist pat tern RP2 having a pat tern opening a part of each upper surface of the pair of conductive layers 4 is formed on the insulating film 6.

Next, as shown in FIG. 28, a pair of holes CH2 are formed inside the insulating film 6 by an anisotropic etching process using the resist pattern RP2 as a mask. Then, the resist pattern RP2 is removed by an asking process.

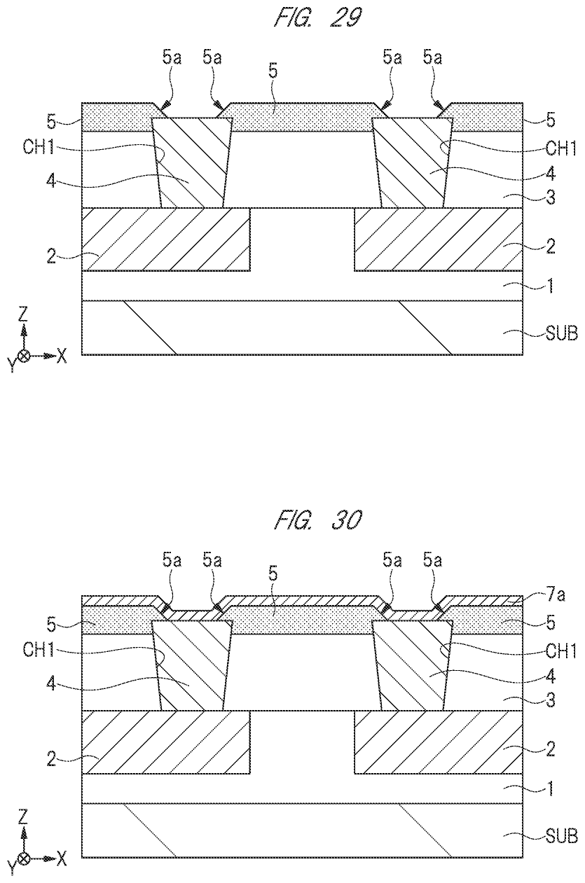

Next, as shown in FIG. 29, an anisotropic etching process is performed to the insulating film 5 and the insulating film 6. This anisotropic etching process is performed under a condition having almost the same etching rate between the insulating film 5 and the insulating film 6. This anisotropic etching process is performed by an EPD (End Point Detector) technique. In other words, this anisotropic etching process is performed until the insulating film 5 is exposed by removal of the insulating film 6 formed on the insulating film 5.

By this anisotropic etching process, the insulating film 5 remains between each upper surface of the pair of conductive layers 4 and the upper surface of the interlayer insulating film 3. In the third embodiment, the insulating film 5 remains so as to cover a part of each upper surface of the pair of conductive layers 4 and the upper surface of the interlayer insulating film 3. In a portion not covered with the insulating film 5, a part of the upper surface of the conductive layer 4 is exposed.

By the anisotropic etching process, the insulating film 5 is provided with the incline surface 5a that inclines with respect to each upper surface of the pair of conductive layers 4 and the interlayer insulating film 3.

Next, as shown in FIG. 30, the resistive material film 7a is formed on each upper surface of the pair of conductive layers 4 and on the upper surface of the insulating film 5 formed on the upper surface of the interlayer insulating film 3 by a sputtering method.

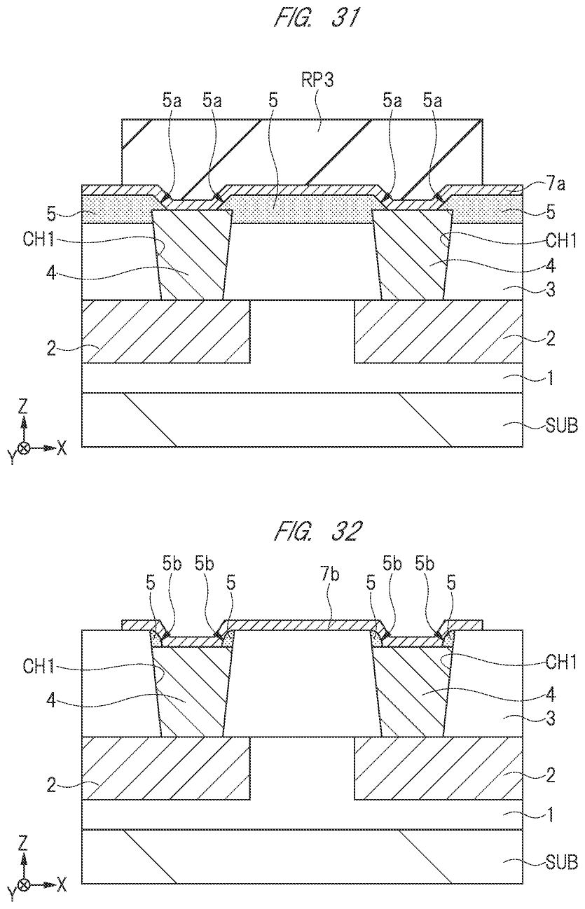

Next, as shown in FIG. 31, a resist pattern RP3 having a pattern covering at least each upper surface of the pair of conductive layers 4 and a portion between the pair of conductive layers 4 is formed on the resistive material film 7a.

Next, the resistive material film 7a is selectively patterned by an anisotropic etching process using the resist pattern RP3 as a mask. In this manner, as shown in FIG. 24, the resistive element 7b connected to the pair of conductive layers 4 is formed. The resistive element 7b is formed along the incline surface 5a so as to cover the insulating film 5. Then, the resist pattern RP3 is removed by an ashing process.

### Fourth Embodiment

With reference to FIGS. 32 to 36, a semiconductor device according to a fourth embodiment and a method of manufacturing the same will be explained below. In the following explanation, differences from the first embodiment will be mainly explained, and the explanation for overlapping points with the first embodiment will be omitted.

### Structure of Semiconductor Device According to Fourth Embodiment

In the first embodiment, by the manufacturing steps using the insulating film 5 and the insulating film 6, the insulating film 5 is eventually formed in the portion where the step is generated. In the fourth embodiment, only the insulating film 5 is used.

As shown in FIG. 32, even in the fourth embodiment, the step is generated between each upper surface of the pair of conductive layers 4 and the upper surface of the interlayer insulating film 3. In other words, a position of each upper surface of the pair of conductive layers 4 is different from a position of the upper surface of the interlayer insulating film 3, and is higher than the position of the upper surface of the interlayer insulating film 3.

In the portion where the step is generated, the insulating film 5 is formed. The insulating film 5 is formed so as to cover a part of each upper surface of the pair of conductive layers 4, and has an incline surface 5b that inclines with respect to each upper surface of the pair of conductive layers 4 and the interlayer insulating film 3.

The resistive element 7b is formed on each upper surface of the pair of conductive layers 4 and the upper surface of the insulating film 5 formed on the upper surface of the interlayer insulating film 3 so as to be connected to each of the pair of conductive layers 4. In the portion where the step is generated, the resistive element 7b is formed along the incline surface 5b so as to cover the insulating film 5.

The incline surface 5b inclines so as to ascend from each of the pair of conductive layers 4 toward the interlayer insulating film 3. In this point, the incline surface 5b is the same as the incline surface 5a. Therefore, as similar to the first embodiment, the fourth embodiment can also solve the problem of the variation in the resistance value of the resistive element 7b or the problem of the short-circuit on the resistive element 7b even when the height difference on the step is large in comparison with the study example. Therefore, even in the fourth embodiment, the reliability of the semiconductor device can be improved.

In this case, the incline surface 5a of the first embodiment linearly inclines within a range of, for example, 40 to 50 degrees. However, the incline surface 5b of the fourth embodiment is processed to have a sidewall spacer form. In other words, the incline surface 5b of the first embodiment is curved so as to be nearly vertical at a portion near the conductive layer 4 and so as to he more horizontal as being closer to the interlayer insulating film 3.

Therefore, as seen in the portion near the conductive layer 4, the incline surface 5b has a portion at which the thickness of the resistive material film 7a tends to be thinner than the incline surface 5a. Thus, in the viewpoint of the improvement of the reliability of the semiconductor device, the first embodiment is more excellent than the fourth embodiment.

However, the fourth embodiment has the number of the steps of manufacturing the semiconductor device and the number of the masks that are less than those of the first embodiment, and therefore, has an effect capable of suppressing a manufacturing cost. A method of manufacturing the semiconductor device according to the fourth embodiment will be explained below.

### Method of Manufacturing Semiconductor Device According to Fourth Embodiment

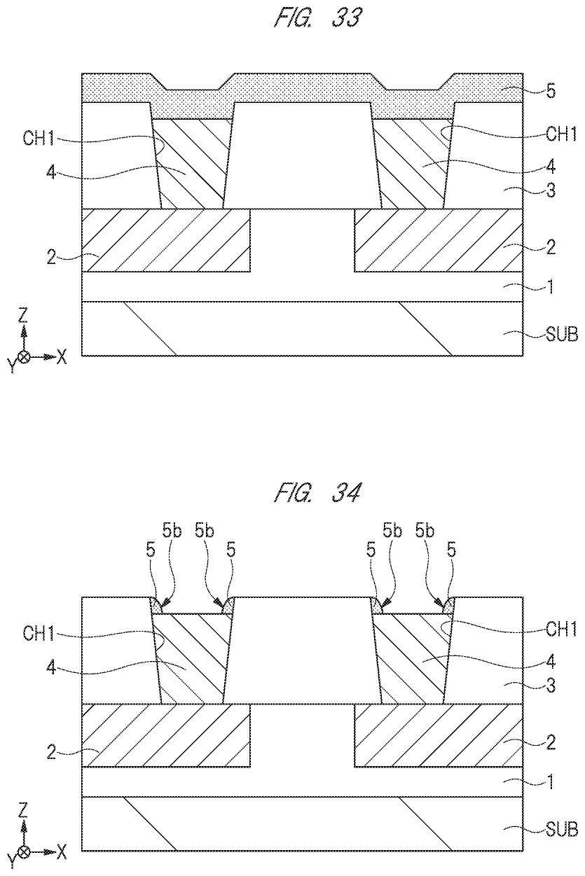

FIG. 33 shows a manufacturing step continued from FIG. 5 of die first embodiment. First, as shown in FIG. 33, the insulating film 5 is formed on each upper surface of the pair of conductive layers 4 and the insulating film 3 so as to cover the step generated between the upper surface of the conductive layer 4 and the upper surface of the insulating film 3.

Next, as shown in FIG. 34, by an anisotropic etching process to the insulating film 5, the insulating film 5 having the sidewall spacer form remains between each upper surface of the pair of conductive layers 4 and the upper surface of the insulating film 3. In the fourth embodiment, the insulating film 5 remains so as to cover a part of each upper surface of the pair of conductive layers 4. In a portion not covered with the insulating film 5, a part of the upper surface of the conductive layer 4 is exposed.

By the anisotropic etching process, the insulating film 5 is provided with the incline surface 5b that inclines with respect to each upper surface of the pair of conductive layers 4 and the interlayer insulating film 3.

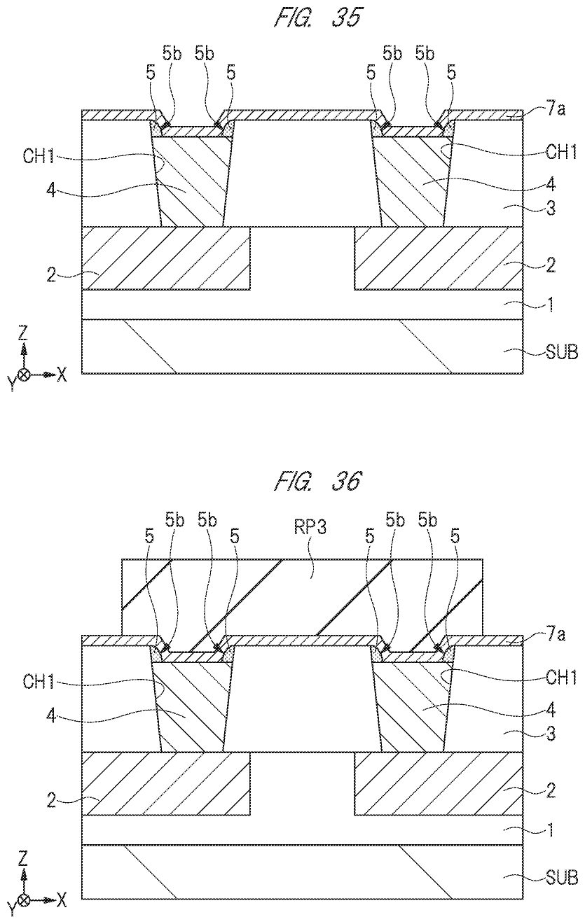

Next, as shown in FIG. 35, the resistive material film 7a is formed on each upper surface of the pair of conductive layers 4 and the upper surface of the insulating film 5 formed on the upper surface of the interlayer insulating film 3 by a sputtering method.

Next, as shown in FIG. 36, a resist pattern RP3 having a pattern covering at least each upper surface of the pair of conductive layers 4 and a portion between the pair of conductive layers 4 is formed on the resistive material film 7a.

Next, the resistive material film 7a is selectively patterned by an anisotropic etching process using the resist pattern RP3 as a mask. In this manner, as shown in FIG. 32, the resistive element 7b connected to the pair of conductive layers 4 is formed. The resistive element 7b is formed along the incline surface 5b so as to cover the insulating film 5. Then, the resist pattern RP3 is removed by an ashing process.

Since the fourth embodiment does not include the steps forming the insulating film 6, the resist pattern RP2 and the hole CH2 explained in the first embodiment as described above, the fourth embodiment can suppress the manufacturing cost for these steps.

Note that the technique disclosed in the fourth embodiment is also applicable to the second embodiment. In this case, the insulating film 5 having the incline surface 5b is formed between each upper surface of the pair of conductive layers 8 and the upper surface of the interlayer insulating film 3 so as to cover a part of the upper surface of the interlayer insulating film 3. In this case, the incline surface 5b inclines so as to descend from each of the pair of conductive layers 8 toward the interlayer insulating film 3.

Also, the technique disclosed in the fourth embodiment is also applicable to the third embodiment. In this case, the insulating film 5 having the incline surface 5b is formed between each upper surface of the pair of conductive layers 4 and the upper surface of the interlayer insulating film 3 so as to cover a part of the upper surface of the interlayer insulating film 3. In this case, the incline surface 5b inclines so as to descend from each of the pair of conductive layers 4 toward the interlayer insulating film 3.

In the foregoing, the present invention has been concretely described on the basis of the embodiments. However, the present invention is not limited to the foregoing embodiments, and various modifications can be made within the scope of the present invention.

What is claimed is

1. A semiconductor device comprising
a semiconductor substrate;
an interlayer insulating film formed on the semiconductor substrate;
a pair of conductive layers formed on the semiconductor substrate and separating from each other through the interlayer insulating film; and
a resistive element formed on each upper surface of the pair of conductive layers and the interlayer insulating film so as to be connected to each of the pair of conductive layers,
wherein a position of each upper surface of the pair of conductive layers is different from a position of an upper surface of the interlayer insulating film,
wherein a first insulating film having an incline surface that inclines with respect to each upper surface of the pair of conductive layers and the interlayer insulating film is formed between each upper surface of the pair of conductive layers and the upper surface of the interlayer insulating film, and
wherein the resistive element is formed along the incline surface so as to cover the first insulating film.

2. The semiconductor device according to claim 1,
wherein each of the pair of conductive layers is buried inside a first hole formed inside the interlayer insulating film.

3. The semiconductor device according to claim 2,
wherein the position of each upper surface of the pair of conductive layers is lower than the position of the upper surface of the interlayer insulating film,
the first insulating film is formed so as to cover at least a part of each upper surface of the pair of conductive layers, and
the incline surface inclines so as to ascend from each of the pair of conductive layers toward the interlayer insulating film.

4. The semiconductor device according to claim 2,
wherein the position of each upper surface of the pair of conductive layers is higher than the position of the upper surface of the interlayer insulating film,
the first insulating film is formed so as to cover a part of each upper surface of the pair of conductive layers and the upper surface of the interlayer insulating film, and
the incline surface inclines so as to ascend from each of the pair of conductive layers toward the interlayer insulating film.

5. The semiconductor device according to claim 1,
wherein the position of each upper surface of the pair of conductive layers is higher than the position of the upper surface of the interlayer insulating film,
the first insulating film is formed so as to cover a part of the upper surface of the interlayer insulating film, and
the incline surface inclines so as to descend from each of the pair of conductive layers toward the interlayer insulating film.

6. The semiconductor device according to claim 1,
wherein an angle that is made by the incline surface and each upper surface of the pair of conductive layers or an angle that is made by the incline surface and the upper surface of the interlayer insulating film is within a range of 40 to 50 degrees.

7. The semiconductor device according to claim 1,
wherein the resistive element is made of SiCr.

8. A method of manufacturing a semiconductor device comprising the steps of:
(a) forming an interlayer insulating film and a pair of conductive layers that separate from each other through the interlayer insulating film, on a semiconductor substrate;
(b) after the step (a), forming a first insulating film on each upper surface of the pair of conductive layers and the interlayer insulating film;
(c) after the step (b), exposing at least apart of each upper surface of the pair of conductive layers by an anisotropic etching process to the first insulating film;
(d) after the step (c), forming a resistive material film on each upper surface of the pair of conductive layers and the interlayer insulating film by a sputtering method; and
(e) after the step (d), forming a resistive element connected to each of the pair of conductive layers by selectively patterning the resistive material film,
wherein, in the step (a), a position of each upper surface of the pair of conductive layers is different from a position of an upper surface of the interlayer insulating film,
wherein, in the step (c), the first insulating film remains between each upper surface of the pair of conductive layers and the upper surface of the interlayer insulating film, and the first insulating film is provided with an incline surface that inclines with respect to each upper surface of the pair of conductive layers and the interlayer insulating film, and,
wherein, in the step (e), the resistive element is formed along the incline surface so as to cover the first insulating film.

9. The method of manufacturing the semiconductor device according to claim 8,
wherein the step (a) includes the steps of:
(a1) forming the interlayer insulating film on the semiconductor substrate;
(a2) after the step (a1), forming a pair of first holes that separate from each other, inside the interlayer insulating film; and
(a3) after the step (a2), burying the conductive layer into each of the pair of first holes.

10. The method of manufacturing the semiconductor device according to claim 9,
wherein, in the step (a3), the position of each upper surface of the pair of conductive layers is lower than the position of the upper surface of the interlayer insulating film,
in the step (c), the first insulating film is formed so as to cover at least a part of each upper surface of the pair of conductive layers, and
the incline surface inclines so as to ascend from each of the pair of conductive layers toward the interlayer insulating film.

11. The method of manufacturing the semiconductor device according to claim 9,
wherein, in the step (a3), the position of each upper surface of the pair of conductive layers is higher than the position of the upper surface of the interlayer insulating film,
in the step (c), the first insulating film is formed so as to cover a part of each upper surface of the pair of conductive layers and the upper surface of the interlayer insulating film, and
the incline surface inclines so as to ascend from each of the pair of conductive layers toward the interlayer insulating film.

12. The method of manufacturing the semiconductor device according to claim 9, further comprising the step of:
(f) between the step (b) and the step (c), forming a second insulating film made of a material that is different from a material configuring the first insulating film, on the first insulating film,
wherein the step (c) includes the steps of
(c1) forming a pair of second holes inside the second insulating film so as to overlap the pair of conductive layers in a planar view; and
(c2) after the step (c1), performing an anisotropic etching process to the second insulating film and the first insulating film until the first insulating film is exposed by removal of the second insulating film that is formed on the first insulating film.

13. The method manufacturing the semiconductor device according to claim 12,
wherein each opening diameter of the pair of second holes is smaller than each opening diameter of the pair of first holes.

14. The method of manufacturing the semiconductor device according to claim 8,
wherein the step (a) includes the steps
(a4) forming the interlayer insulating film on the semiconductor substrate; and
(a5) after the step (a4), forming the pair of conductive layers on the upper surface of the interlayer insulating film.

15. The method of manufacturing the semiconductor device according to claim 14,
wherein, in the step (a5), the position of each upper surface of the pair of conductive layers is higher than the position of the upper surface of the interlayer insulating film,
in the step (c), the first insulating film remains so as to cover a part of the upper surface of the interlayer insulating film, and
the incline surface inclines so as to descend from each of the pair of conductive layers toward the interlayer insulating film.

16. The method of manufacturing the semiconductor device according to claim 15, further comprising the step of:
(g) between the step (b) and the step (c), forming a second insulating film made of a material that is different from a material configuring the first insulating film, on the first insulating film,
wherein the step (c) includes the steps of:
(c3) forming a third hole inside the second insulating film that is positioned between the pair of conductive layers; and
(c4) after the step (c3), performing an anisotropic etching process to the second insulating film and the first insulating film until each upper surface of the pair of conductive layers is exposed by removal of the second insulating film and the first insulating film formed on each upper surface of the pair of conductive layers.

17. The method of manufacturing the semiconductor device according to claim 8,
wherein an angle that is made by the incline surface and each upper surface of the pair of conductive layers or an angle that is made by the incline surface and the upper surface of the interlayer insulating film is within a range of 40 to 50 degrees.

18. The method of manufacturing the semiconductor device according to claim 8,
wherein the resistive material film is made of SiCr.
